(19) United States
(12) Patent Application Publication
(10) Pub. No.: US 2025/0246851 A1
(43) Pub. Date: Jul. 31, 2025

(54) SHIELDED ELECTRICALLY CONDUCTIVE PATH

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Tatsuki SATOOKA, Osaka (JP); Kazuaki HAMADA, Osaka (JP); Shohei TAKEGASA, Osaka (JP)

(21) Appl. No.: 18/854,979

(22) PCT Filed: Mar. 28, 2024
(86) PCT No.: PCT/JP2023/012595

§ 371 Date: Oct. 8, 2024

(30) Foreign Application Priority Data
Apr. 15, 2022 (JP) 2022-067470

(51) Int. Cl. H01R 13/631; H01B 7/02; H01R 13/02; H01R 13/22; H01R 13/6592

(52) U.S. Cl. CPC H01R 13/631; H01B 7/0216; H01B 7/0266; H01R 13/025; H01R 13/22; H01R 13/6592

(57) ABSTRACT

A shielded electrically conductive path (100) includes a shielded cable (10) formed such that a shield layer (13) surrounding a core wire (11) is surrounded by a sheath (14), a sleeve (15) arranged to surround an outer periphery of the shield layer (13) extending forward in an axial direction of the shielded cable (10) from a front end of the sheath (14), and a butting portion (15) extending forward in the axial direction from a rear end of the sleeve (15) and configured to contact the front end of the sheath (14).

### TECHNICAL FIELD

The present disclosure relates to a shielded electrically conductive path.

### BACKGROUND

Patent Document 1 discloses a connector device in which a sleeve is arranged at a position separated from a sheath in an axial direction. In this, a holding member provided on the sleeve has a function of applying a force acting radially inward to a cable. That is, the holding member is bent radially inwardly, whereby the position of the sleeve is held in an axial direction of the cable.

### PRIOR ART DOCUMENT

### Patent Document

Patent Document 1: JP 2019-021632 A

### SUMMARY OF THE INVENTION

### Problems to be Solved

In the connector device of Patent Document 1, a force is applied to the sleeve in a direction approaching the sheath such as when an outer conductor is assembled or an external conductor (braided wire) is folded. There is a concern that the position of the sleeve is shifted toward the sheath from a proper position by this force.

A connector of the present disclosure aims to prevent a position shift of a sleeve.

### Means to Solve the Problem

The present disclosure is directed to a shielded electrically conductive path with a shielded cable formed such that a shield layer surrounding a core wire is surrounded by a sheath, a sleeve arranged to surround an outer periphery of the shield layer extending forward in an axial direction of the shielded cable from a front end of the sheath, and a butting portion extending rearward in the axial direction from a rear end of the sleeve, the butting portion contacting the front end of the sheath.

### Effect of the Invention

According to the present disclosure, a position shift of a sleeve can be prevented.

### BRIEF DESCRIPTION OF THE DRAWINGS

FIG. 1 is a side view in section of a shielded electrically conductive path.

FIG. 2 is a development of a sleeve and a butting portion.

FIG. 3 is a section along A-A in FIG. 1.

FIG. 4 is a section along A-A in FIG. 1 showing a state before a rear part of a first outer conductor is crimped.

FIG. 5 is a partial development of the first outer conductor.

FIG. 6 is a perspective view showing a sleeve in another embodiment.

FIG. 7 is a perspective view showing a sleeve in another embodiment.

FIG. 8 is a back view showing a sleeve in another embodiment.

FIG. 9 is a side view showing the sleeve in the other embodiment.

### DETAILED DESCRIPTION TO EXECUTE THE INVENTION

### Description of Embodiments of Present Disclosure

First, embodiments of the present disclosure are listed and described.

(1) The shielded electrically conductive path of the present disclosure is provided with a shielded cable formed such that a shield layer surrounding a core wire is surrounded by a sheath, and a sleeve arranged to surround an outer periphery of the shield layer extending forward in an axial direction of the shielded cable from a front end of the sheath. The shielded electrically conductive path is further provided with a butting portion extending rearward in the axial direction from a rear end of the sleeve and configured to contact the front end of the sheath. According to this configuration, even if a rearward external force is applied to the sleeve, the sleeve can be reliably prevented from being shifted in a direction approaching the sheath by the butting portion.

(2) Preferably, in (1), a dimension of a rear end of the butting portion is larger than a dimension of a front end part of the butting portion in a radial direction of the shielded cable. According to this configuration, since the dimension of the rear end of the butting portion is larger than the dimension of the front end part of the butting portion, the butting portion is easily held in contact with the front end of the sheath by being prevented from slipping under the sheath.

(3) Preferably, in (2), a rear end part of the butting portion is bent outward in the radial direction. According to this configuration, an effect of holding the butting portion in contact with the front end of the sheath can be exhibited by preventing the butting portion from slipping under the sheath.

(4) Preferably, in (2), a rear end part of the butting portion is formed with a curved surface folded outward in the radial direction and forward and curved rearward. According to this configuration, the butting portion can be brought into contact with the front end of the sheath without damaging the front end of the sheath.

(5) Preferably, in (2), a facing surface of the sleeve facing the outer periphery of the shield layer and a facing surface of the butting portion facing the outer periphery of the shield layer are continuous and flush with each other in the axial direction. According to this configuration, since the shield layer is not pressed, electrical properties of the shielded cable are not damaged.

(6) Preferably, in (2), a radius of curvature in a rear end part of the butting portion is smaller than a radius of curvature of the sleeve when the butting portion is viewed from the axial direction. According to this configuration, since the shield layer is not pressed, electrical properties of the shielded cable are not damaged.

(7) In (1) to (6), an outer conductor is further provided which surrounds an outer periphery of a front end part of the sheath, an outer periphery of the sleeve and an outer periphery of the butting portion. A part surrounding a separation region formed between the sheath and the sleeve, out of the outer conductor, is formed with a recess recessed radially inward of the shielded cable. A formation region of the recess in a circumferential direction of the shielded cable is preferably a region except an arranged part of the butting portion in the separation region. According to this configuration, since the butting portion is not pressed by the outer conductor, the shield layer is not pressed and electrical properties of the shielded cable are not damaged.

### Details of Embodiments of Present Disclosure

### First Embodiment

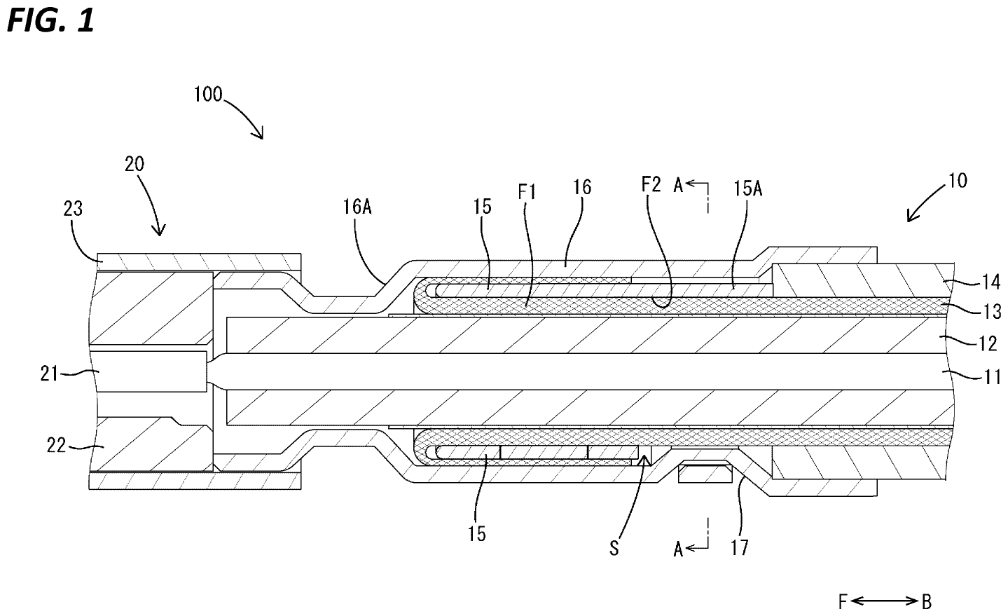

A first specific embodiment of the present disclosure is described with reference to FIGS. 1 to 5. In figures, a “front side” and a “rear side” are respectively denoted by “F” and “B”.

As shown in FIG. 1, a shielded electrically conductive path 100 is provided with a shielded cable 10, a sleeve 15 externally fit to the shielded cable 10, a butting portion 15A, a first outer conductor 16, which is an outer conductor, and a shield terminal 20 connected to a front end part of the shielded cable 10. The shielded cable 10 is formed such that a core wire 11 is surrounded by an insulation coating 12, a shield layer 13 constituted by a braided wire braided into a tubular shape is overlaid on the outer periphery of the insulation coating 12, and the outer periphery of the shield layer 13 is surrounded by the sheath 14. That is, the shielded cable 10 is formed such that the shield layer 13 surrounding the core wire 11 is surrounded by the sheath 14.

The shielded cable 10 is arranged with an axial direction oriented in a front-rear direction. In the following description, the front-rear direction and the axial direction are used as synonyms. In a front end part of the shielded cable 10, the sheath 14 and the insulation coating 12 are removed, and the core wire 11 is exposed in front of the insulation coating 12. The sheath 14 is removed behind the exposed core wire 11 to expose the shield layer 13.

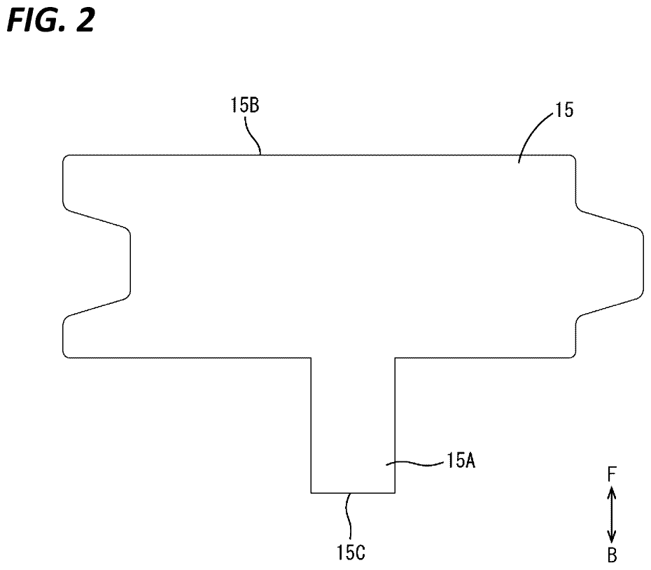

The sleeve 15 is formed into a hollow cylindrical shape by press-working an electrically conductive plate material of metal or the like. The butting portion 15A is formed to extend rearward from the rear end edge of the sleeve 15. As shown in FIG. 2, the butting portion 15A is formed in a central part in a width direction on the rear end edge of the sleeve 15 in a developed state. Note that the sleeve 15 is preferably coupled to a carrier at either a front end edge 15B of the sleeve 15 or a rear end edge 15C of the butting portion 15A.

As shown in FIG. 1, a facing surface F1 of the sleeve 15 facing the outer periphery of the shield layer 13 and a facing surface F2 of the butting portion 15A facing the outer periphery of the shield layer 13 are continuous and flush with each other in the front-rear direction (axial direction). The sleeve 15 is arranged to surround the outer periphery of the shield layer 13 extending forward in the axial direction of the shielded cable 10. The butting portion 15A extends rearward in the axial direction from the rear end of the sleeve 15. The rear end of the butting portion 15A is in contact with the front end of the sheath 14. The outer periphery of the sleeve 15 is covered by a front end part of the shield layer 13 folded rearward. The rear end of the sleeve 15 and the front end of the sheath 14 are separated in the axial direction by the butting portion 15A. A separation region S is formed between the rear end of the sleeve 15 and the front end of the sheath 14.

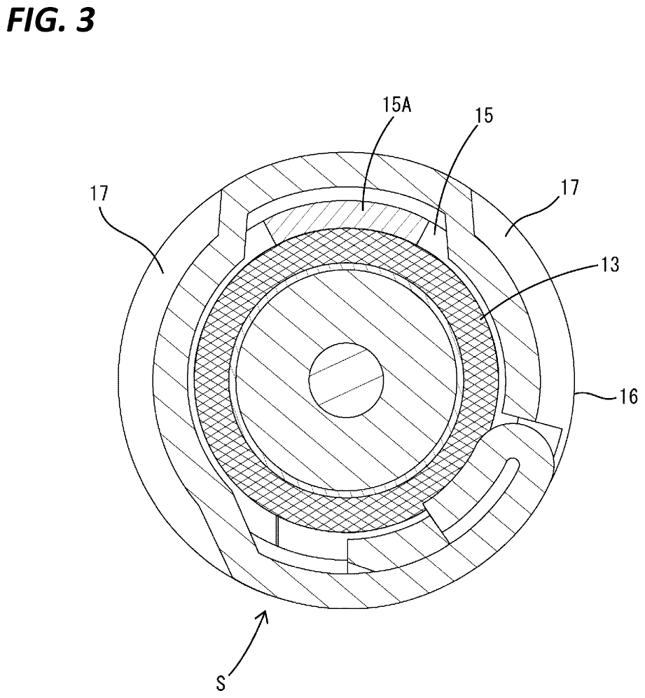

The first outer conductor 16 has a hollow cylindrical shape and extends in the front-rear direction. The first outer conductor 16 is arranged to surround the outer periphery of the insulation coating 12, that of the front end part of the sheath 14, that of the sleeve 15 and that of the butting portion 15A. A front part of the first outer conductor 16 is formed with a reduced diameter portion 16A recessed over an entire circumference. The reduced diameter portion 16A is arranged in front of and adjacent to the front end of the folded shield layer 13. A part of the first outer conductor 16 surrounding the separation region S is formed with a recess 17 recessed radially inward of the shielded cable 10. A formation region of the recess 17 in a circumferential direction of the shielded cable 10 (hereinafter, merely referred to as a circumferential direction) is a region except an arranged part of the butting portion 15A in the separation region S (see FIG. 3).

The shield terminal 20 is provided with an inner conductor 21 connected to a front end part of the core wire 11, a dielectric 22 accommodating the inner conductor 21 and a second outer conductor 23 having a hollow cylindrical shape and surrounding the outer periphery of the dielectric 22. An axial direction of the second outer conductor 23 is coaxial with that of the shielded cable 20 and oriented in the front-rear direction. A rear end part of the second outer conductor 23 is externally fit to a front end part of the first outer conductor 16 and coupled to the first outer conductor 16 by spot welding or the like.

Next, an example of an assembly process of the shielded electrically conductive path 100 is described. First, in the front end part of the shielded cable 10, the sheath 14 and the insulation coating 12 are removed to expose the core wire 11 in front of the insulation coating 12. Behind the exposed core wire 11, the sheath 14 is removed to expose the shield layer 13.

Subsequently, the sleeve 15 is mounted. Specifically, the posture of the sleeve 15 is so oriented that the butting portion 15A projects rearward. Then, the sleeve 15 is arranged to surround the outer periphery of the shield layer 13. At this time, the rear end of the butting portion 15A is brought into contact with the front end of the sheath 14 (see FIG. 1). In this way, the separation region S is formed between the rear end of the sleeve 15 and the front end of the sheath 14 (see FIG. 1).

Subsequently, the shield layer 13 located in front of the sleeve 15 is folded rearward to cover the outer periphery of the sleeve 15 (see FIG. 1). In folding the shield layer 13 rearward, a rearward force is applied to the sleeve 15 from the shield layer 13. However, since the rear end of the butting portion 15A is in contact with the front end of the sheath 14, the position of the sleeve 15 is not shifted rearward.

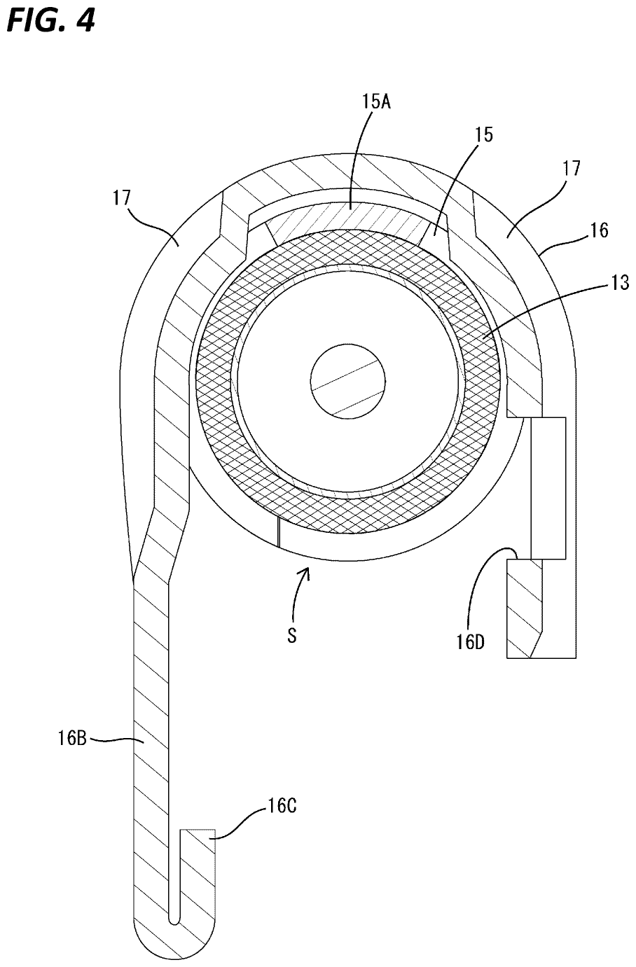

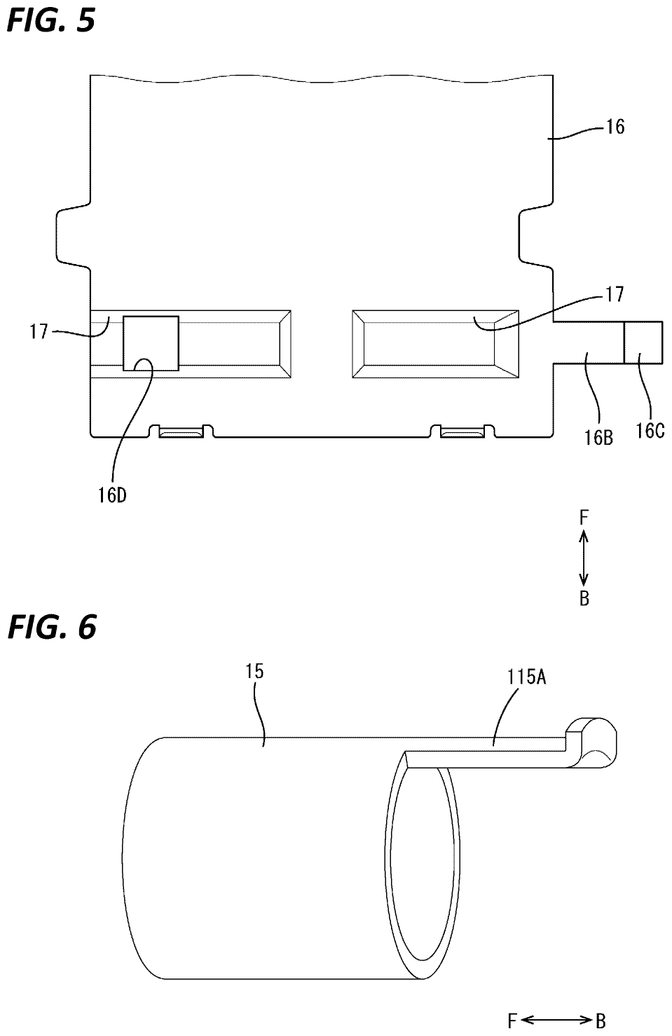

Subsequently, the first outer conductor 16 is mounted. As shown in FIG. 4, the recess 17 is formed in advance in a state before crimping on a rear side of the first outer conductor 16, and a circumferential part is cut open. A locking piece 16B extending in a tangential direction is provided on one end edge of the cut-open part of the first outer conductor 16. A locking portion 16C folded inward is provided on a tip part of the locking piece 16B. The locking piece 16B is arranged in a direction orthogonal to the front-rear direction with respect to the recess 17 (see FIG. 5). A through hole 16D penetrating in a plate thickness direction is formed in the other end edge part of the cut-open part of the first outer conductor 16. The through hole 16D is arranged in a formation range of the recess 17 (see FIG. 5). The first outer conductor 16 is mounted on the shielded cable 10 while being partially cut open in the circumferential direction. At this time, the position of the butting portion 15A in the circumferential direction is arranged to face a region where the recess 17 is not formed. Along with this, the tip part of the shielded cable 10 is inserted to a position where the front end of the folded shield layer 13 is adjacent to the rear end of the reduced diameter portion 16A (see FIG. 1).

Subsequently, the first outer conductor 16 is crimped. By crimping the first outer conductor 16, the end edges of the cut-open part of the first outer conductor 16 are butted against each other. Then, the locking piece 16B is plastically deformed along the circumferential direction of the shielded cable 10 and the locking portion 16C enters the through hole 16D from an outer peripheral side (see FIG. 3). In this way, the end edges of the cut-open part of the first outer conductor 16 are held in a state butting against each other (see FIG. 3). Then, the shield terminal 20 is mounted on the front end part of the shielded cable 10 to complete the shielded electrically conductive path 100 (see FIG. 1).

Next, functions of the first embodiment are described.

The shielded electrically conductive path 100 is provided with the shielded cable 10, in which the shield layer 13 surrounding the core wire 11 is surrounded by the sheath 14, and the sleeve 15 arranged to surround the outer periphery of the shield layer 13 extending forward in the axial direction of the shielded cable 10 from the front end of the sheath 14. The shielded electrically conductive path 100 is further provided with the butting portion 15A extending rearward in the axial direction from the rear end of the sleeve 15 and configured to contact the front end of the sheath 14. According to this configuration, even if a rearward external force is applied to the sleeve 15, the sleeve 15 can be reliably prevented from being shifted in a direction approaching the sheath 14 by the butting portion 15A.

The facing surface F1 of the sleeve 15 facing the outer periphery of the shield layer 13 and the facing surface F2 of the butting portion 15A facing the outer periphery of the shield layer 13 are continuous and flush with each other in the axial direction. According to this configuration, since the shield layer 13 is not pressed, electrical properties of the shielded cable 10 are not damaged.

The first outer conductor 16 is further provided which surrounds the outer periphery of the front end part of the sheath 14, that of the sleeve 15 and that of the butting portion 15A. A part surrounding the separation region S formed between the sheath 14 and the sleeve 15, out of the first outer conductor 16, is formed with the recess 17 recessed radially inward of the shielded cable 10. The formation region of the recess 17 in the circumferential direction of the shielded cable 10 is the region except the arranged part of the butting portion 15A in the separation region S. According to this configuration, since the butting portion 15A is not pressed by the first outer conductor 16, the shield layer 13 is not pressed and electrical properties of the shielded cable 10 are not damaged.

### Other Embodiments

The present disclosure is not limited to the above described and illustrated first embodiment. The present invention is intended to include all changes in the scope of claims and in the meaning and scope of equivalents and also include the following embodiments.

(1) As shown in FIG. 6, a dimension of the rear end of a butting portion 115A may be larger than a dimension of a front end part of the butting portion 115A in the radial direction of the shielded cable 10. According to this configuration, since the dimension of the rear end of the butting portion 115A is larger than the dimension of the front end part of the butting portion 115A, the butting portion 15A is easily held in contact with the front end of the sheath 14 by being prevented from slipping under the sheath 14. Further, a rear end part of the butting portion 115A may be bent radially outward of the shielded cable 10. According to this configuration, an effect of holding the butting portion 15A in contact with the front end of the sheath 14 by preventing the butting portion 15A from slipping under the sheath 14 is exhibited. In this case, it is considered to avoid interference with the rear end part of the butting portion 115A by cutting the first outer conductor 16 located at the rear end part of the butting portion 15A.

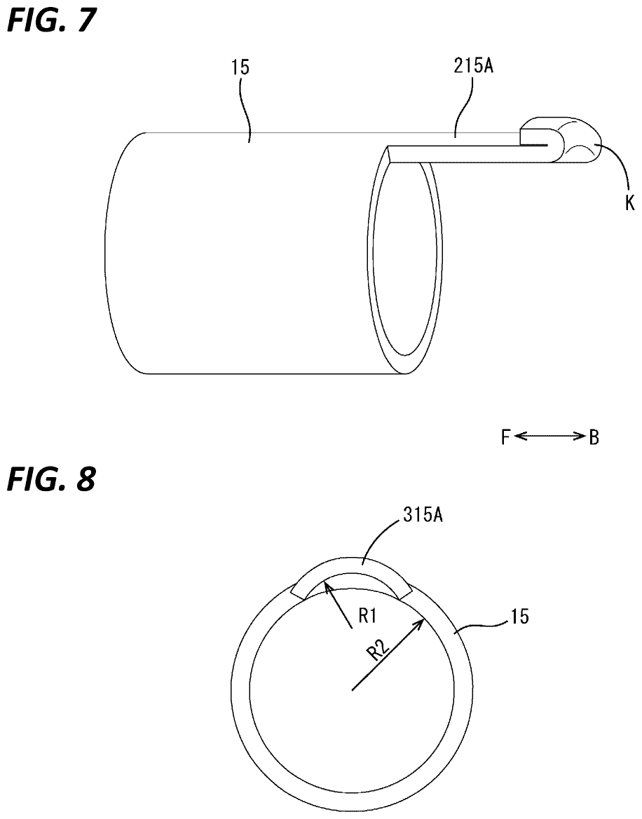

(2) As shown in FIG. 7, a curved surface K folded radially outward of the shielded cable 10 and forward and curved rearward may be formed on a rear end part of a butting portion 215A. According to this configuration, the rear end of the butting portion 215A can be brought into contact with the front end of the sheath 14 without damaging the front end of the sheath 14. In the radial direction of the shielded cable 10, a dimension of the rear end of the butting portion 215A is larger than a dimension of a front end part of the butting portion 215A.

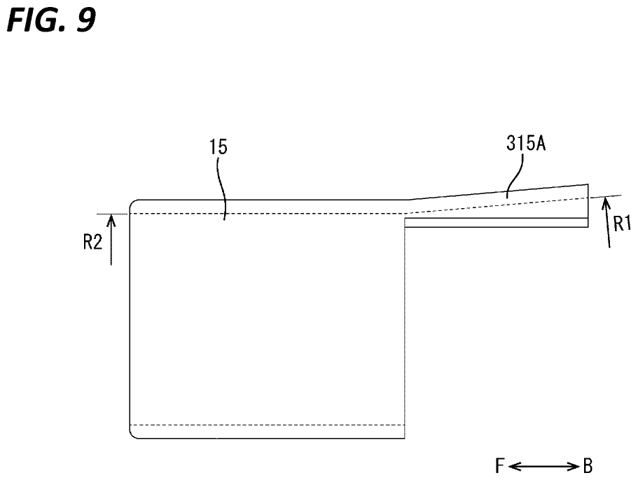

(3) As shown in FIG. 8, when a butting portion 315A is viewed from the axial direction, a radius of curvature R1 in a rear end part of the butting portion 315A may be smaller than a radius of curvature R2 of the sleeve 15. Specifically, as shown in FIG. 9, a radius of curvature of the butting portion 315A is set equal to the radius of curvature R1 of the sleeve 15 at a front end and gradually reduced toward a rear end. According to this configuration, since the shield layer 13 is not pressed, electrical properties of the shielded cable 10 are not damaged. In the radial direction of the shielded cable 10, a dimension of the rear end of the butting portion 315A is larger than a dimension of a front end part of the butting portion 315A.

(4) Unlike the above first embodiment, a plurality of the butting portions may be provided. Further, the butting portion may be arranged on an end part in the width direction on the rear end edge of the sleeve in the developed state.

(5) Unlike the above first embodiment, the sleeve may have a polygonal tube shape.

(6) Unlike the above first embodiment, a bead extending in the front-rear direction may be formed from the rear part of the sleeve to the front part of the butting portion. The bead preferably projects radially outward.

### LIST OF REFERENCE NUMERALS

10 . . . shielded cable
11 . . . core wire
12 . . . insulation coating
13 . . . shield layer
14 . . . sheath
15 . . . sleeve
15A, 115A, 215A, 315A . . . butting portion
15B . . . front end edge
15C . . . rear end edge
16 . . . first outer conductor (outer conductor)
16A . . . reduced diameter portion
16B . . . locking piece
16C . . . locking portion
16D . . . through hole
17 . . . recess
20 . . . shield terminal
21 . . . inner conductor
22 . . . dielectric
23 . . . second outer conductor
100 . . . shielded electrically conductive path
K . . . curved surface
R1, R2 . . . radius of curvature
S . . . separation region

1. A shielded electrically conductive path, comprising:
a shielded cable formed such that a shield layer surrounding a core wire is surrounded by a sheath;
a sleeve arranged to surround an outer periphery of the shield layer extending forward in an axial direction of the shielded cable from a front end of the sheath; and
a butting portion extending rearward in the axial direction from a rear end of the sleeve, the butting portion contacting the front end of the sheath.

2. The shielded electrically conductive path of claim 1, wherein a dimension of a rear end of the butting portion is larger than a dimension of a front end part of the butting portion in a radial direction of the shielded cable.

3. The shielded electrically conductive path of claim 2, wherein a rear end part of the butting portion is bent outward in the radial direction.

4. The shielded electrically conductive path of claim 2, wherein a rear end part of the butting portion is formed with a curved surface folded outward in the radial direction and forward and curved rearward.

5. The shielded electrically conductive path of claim 2, wherein a facing surface of the sleeve facing the outer periphery of the shield layer and a facing surface of the butting portion facing the outer periphery of the shield layer are continuous and flush with each other in the axial direction.

6. The shielded electrically conductive path of claim 2, wherein a radius of curvature in a rear end part of the butting portion is smaller than a radius of curvature of the sleeve when the butting portion is viewed from the axial direction.

7. The shielded electrically conductive path of claim 1, further comprising an outer conductor for surrounding an outer periphery of a front end part of the sheath, an outer periphery of the sleeve and an outer periphery of the butting portion, wherein:
a part surrounding a separation region formed between the sheath and the sleeve, out of the outer conductor, is formed with a recess recessed radially inward of the shielded cable, and
a formation region of the recess in a circumferential direction of the shielded cable is a region except an arranged part of the butting portion in the separation region.
